(19) United States
(12) Patent Application Publication
(10) Pub. No.: US 2025/0212477 A1
(43) Pub. Date: Jun. 26, 2025

(54) METHOD AND SYSTEM FOR MULTI-CORE ENGINEERED SUBSTRATE

(71) Applicant: QROMIS, Inc., Santa Clara, CA (US)

(72) Inventors: Vladimir Odnoblyudov, Danville, CA (US); Cem Basceri, Los Gatos, CA (US); Casey Kurth, Boise, ID (US)

(73) Assignee: QROMIS, Inc., Santa Clara, CA (US)

(21) Appl. No.: 18/999,690

(22) Filed: Dec. 23, 2024

Related U.S. Application Data
(60) Provisional application No. 63/614,856, filed on Dec. 26, 2023.

(51) Int. Cl. H10D 62/85

(52) U.S. Cl. CPC H10D 62/8503

(57) ABSTRACT

An engineered substrate includes a polycrystalline ceramic core having a device surface and a support surface opposite the device surface and a polycrystalline layer free of a binding agent coupled to the device surface. The polycrystalline grains can include aluminum nitride and the binding agent can include yttrium aluminum garnet. The polycrystalline layer can consist of aluminum nitride and be free of yttrium. An engineered substrate with a polycrystalline shell includes a polycrystalline ceramic core having a device surface, a support surface opposite the device surface, and peripheral surfaces extending between the device surface and the support surface. The engineered substrate with a polycrystalline shell also includes a polycrystalline shell free of a binding agent encapsulating the polycrystalline ceramic core.

### CROSS-REFERENCES TO RELATED APPLICATIONS

This application claims priority to U.S. Provisional Patent Application No. 63/614,856, filed on Dec. 26, 2023, the disclosure of which is hereby incorporated by reference in its entirety for all purposes.

### BACKGROUND OF THE INVENTION

Gallium nitride-based device structures, including light-emitting diode (LED) structures, are typically epitaxially grown on sapphire substrates. Many products currently use LED devices, including lighting, computer monitors, and other display devices. Additionally, gallium nitride-based power electronics are being developed for a wide variety of applications, including electric vehicles and battery systems. Despite the progress made in the area of gallium-nitride-based device structures, there is a need in the art for improved methods and systems related to epitaxial growth processes and substrate structures.

### SUMMARY OF THE INVENTION

Embodiments of the present invention relate to semiconductor devices. More particularly, embodiments utilize a polycrystalline ceramic core with binding agents in conjunction with a ceramic layer free of binding agents to provide a multi-layer core for engineered substrates. The ceramic layer prevents migration of a binding agent, for example, yttrium, yttrium oxide, and/or yttrium-based compounds from the polycrystalline ceramic core to adjacent engineered layers. In the embodiments discussed herein, yttrium oxide is discussed as a binding agent, but the present invention is not limited to this particular binding agent, and other binding agents are included within the scope of the present invention. Embodiments of the present invention are applicable to engineered substrates useful in a variety of semiconductor device designs, including light emitting devices, power transistors, and the like.

Numerous benefits are achieved by way of the present invention over conventional techniques. For example, embodiments of the present invention provide multi-core engineered substrates that include a polycrystalline ceramic core, which includes yttrium-based compounds as a binding agents, and a ceramic layer free of binding agents. The ceramic layer prevents binding agents, for example, yttria and yttrium present in the polycrystalline ceramic core from migrating through the ceramic layer to adjacent engineered layers at elevated temperatures. These and other embodiments of the invention, along with many of its advantages and features, are described in more detail in conjunction with the text below and attached figures.

### BRIEF DESCRIPTION OF THE DRAWINGS

FIG. 1 is a simplified schematic diagram illustrating an engineered substrate structure.

FIG. 2A is a secondary ion mass spectroscopy (SIMS) profile illustrating species concentration (as-deposited) as a function of depth for an engineered structure according to an embodiment of the present invention.

FIG. 2B is a SIMS profile illustrating species concentration (after anneal) as a function of depth for an engineered structure without a diffusion barrier layer according to an embodiment of the present invention.

FIG. 2C is a SIMS profile illustrating species concentration (after anneal) as a function of depth for an engineered structure with a diffusion barrier layer according to an embodiment of the present invention.

FIG. 3 is a simplified schematic diagram illustrating a semiconductor device with yttrium-based compound migration according to an embodiment of the present invention.

FIG. 4 is a simplified schematic diagram illustrating a multi-core engineered substrate structure according to an embodiment of the present invention.

FIG. 5 is a simplified schematic diagram illustrating a multi-core engineered substrate structure according to another embodiment of the present invention.

FIG. 6 is a simplified flowchart illustrating a method of fabricating a multi-core engineered substrate structure according to an embodiment of the present invention.

FIG. 7 is a simplified flowchart illustrating a method of fabricating a multi-core engineered substrate structure by deposition and polishing of a polycrystalline layer according to an embodiment of the present invention.

FIG. 8 is a simplified flowchart illustrating a method of fabricating a multi-core engineered substrate structure with a polycrystalline shell according to an embodiment of the present invention.

### DETAILED DESCRIPTION OF THE INVENTION

The growth of gallium nitride based optoelectronic and electronic structures on a sapphire substrate is a heteroepitaxial growth process since the substrate and the epitaxial layers are composed of different materials. Due to the heteroepitaxial growth process, the epitaxially grown material can exhibit a variety of adverse effects, including reduced uniformity and reductions in metrics associated with the electronic/optical properties of the epitaxial layers.

As a result, engineered substrates have been developed in the past few years, and numerous benefits have been achieved over conventional techniques, as described in U.S. Pat. No. 10,297,445, which is hereby incorporated by reference in its entirety for all purposes.

For instance, engineered substrates can be coefficient of thermal expansion (CTE) matched to gallium nitride-based epitaxial layers suitable for use in optical, electronic, and optoelectronic applications. In addition, encapsulating layers utilized as components of the engineered substrate can block diffusion of impurities present in central portions of the substrate from reaching the semiconductor processing environment in which the engineered substrate is utilized. Thus, the polycrystalline ceramic core can be substantially CTE matched to a polycrystalline layer/polycrystalline shell, the epitaxial film(s) grown on the engineered substrate, or the like. The key properties associated with the substrate material, including the CTE, lattice mismatch, thermal stability, and shape control can be engineered independently for an improved (e.g., an optimized) match with gallium nitride-based epitaxial and device layers, as well as with different device architectures and performance targets. Moreover, since substrate material layers are compatible with and integrated into the conventional semiconductor fabrication processes, process integration is simplified.

However, the inventors have appreciated a number of challenges associated with the engineered substrates in relation to yttria (i.e., yttrium oxide) migration through silicon- containing layers at elevated temperatures.

During fabrication processes for semiconductor structures formed, for example, in device layers, on the engineered substrate, the engineered substrate may experience elevated temperatures (e.g., 1300° C.) in processes such as annealing, ion implantation, and the like. At these elevated temperatures, yttria that is utilized as a binding material, for example, in the polycrystalline ceramic core of the engineered substrate, can consume materials in the engineered substrate and, thereby, damage the engineered substrate. This phenomenon can be referred to as “yttria migration.”

As an example, for an engineered substrate including a single crystal layer used as a substrate for epitaxial crystal growth, migration of yttrium and/or yttrium-based compounds from the polycrystalline ceramic core to the interface between engineered substrate and the single crystal layer can result in localized delamination of the single crystal layer and morphology defects in epitaxial layers grown on the single crystal layer.

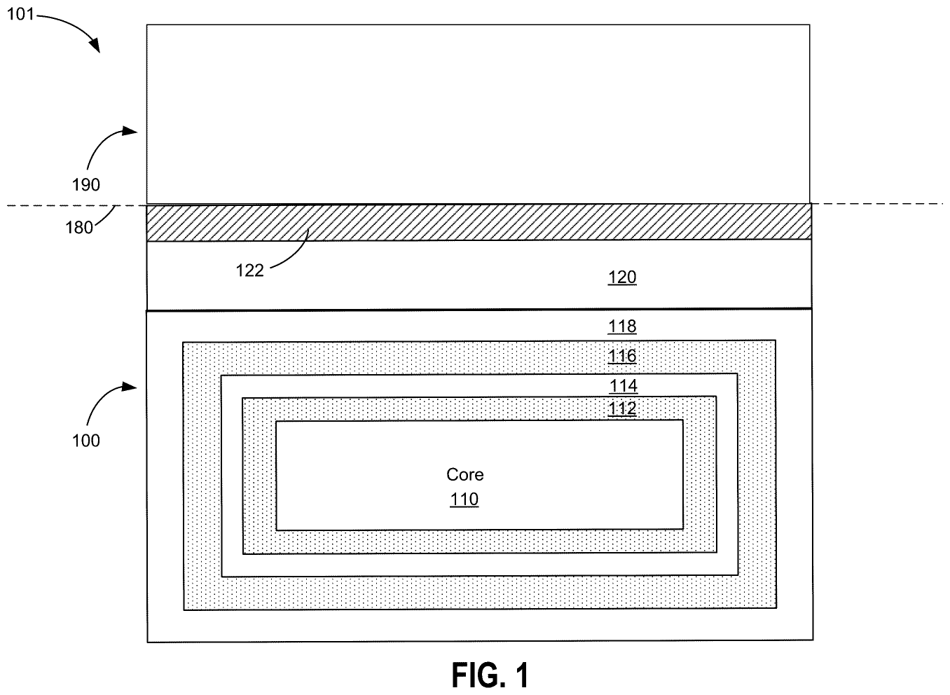

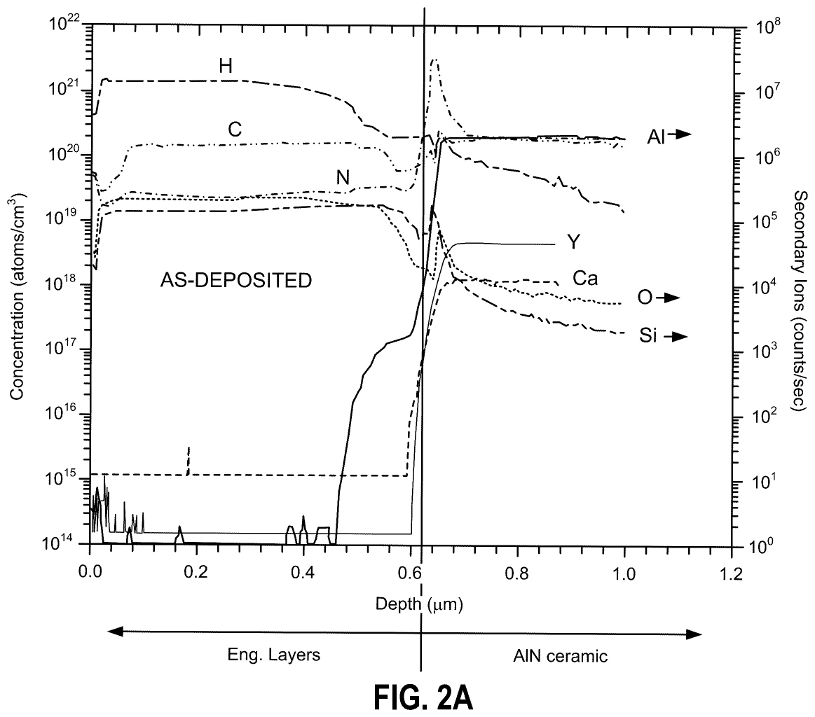

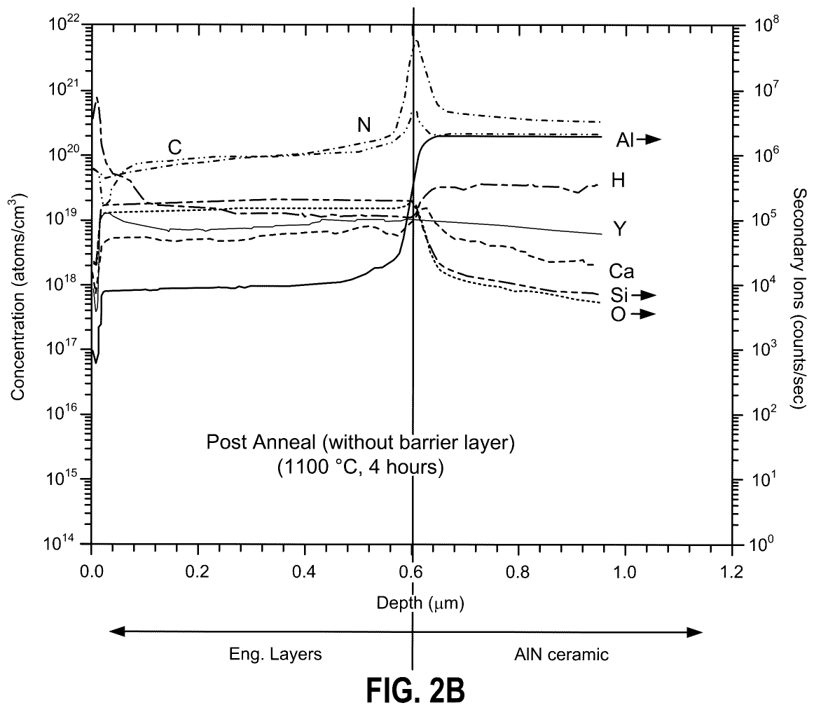

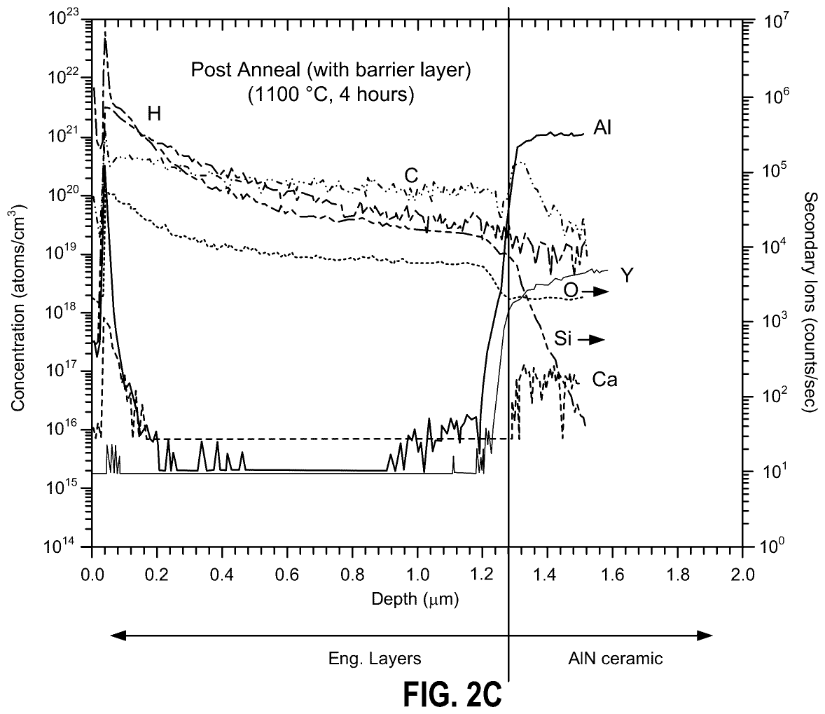

The inventors have observed that a diffusion barrier layer (e.g., a silicon nitride layer), which prevents diffusion and/or outgassing of elements present in the core of the engineered substrate, cannot prevent yttria migration at elevated temperatures, for example, temperatures greater than 1,100° C. As discussed above, yttria migration can lead to the delamination of the device layers, thereby significantly reducing the yield of semiconductor devices fabricated on the engineered substrate. Yttrium diffusion will be discussed in greater detail below with reference to FIGS. 1 and 2A-2C.

FIG. 1 is a simplified schematic diagram illustrating an engineered substrate structure. FIG. 1 is not drawn to scale. As shown in FIG. 1, a semiconductor device 101 includes an engineered substrate 100 and device layers 190 (e.g., multiple device layers) formed on the engineered substrate 100. In one example, the device layers 190 include multiple gallium nitride (GaN) epitaxial layers. Various semiconductor structures can be fabricated based on the device layers 190.

The engineered substrate 100 illustrated in FIG. 1 is suitable for a variety of electronic and optical applications. The engineered substrate includes a core 110 that can have a CTE that is substantially matched to the CTE of the epitaxial material that will be grown on the engineered substrate 100.

For applications including the growth of GaN-based materials (e.g., epitaxial layers including GaN-based layers), the core 110 can be a polycrystalline ceramic material, for example, polycrystalline aluminum nitride (AlN), which can include an yttrium-based compound (e.g., yttria) as a binding agent. Other materials can be utilized in the core 110, including polycrystalline GaN, polycrystalline aluminum gallium nitride (AlGaN), polycrystalline silicon carbide (SiC), polycrystalline zinc oxide (ZnO), polycrystalline gallium trioxide (Ga₂O₃), aluminum oxide (Al₂O₃), aluminum oxynitride (AlON), and the like.

The thickness of the core can be on the order of 100 μm to 1,500 μm, for example, 725 μm. The core 110 is encapsulated in a first adhesion layer 112 that can be referred to as a shell or an encapsulating shell. In an embodiment, the first adhesion layer 112 comprises a silicon oxide layer grown using, for example, a tetraethyl orthosilicate (TEOS) precursor. The first adhesion layer 112 can have a thickness on the order of 1,000 Å. In other embodiments, the thickness of the first adhesion layer 112 varies, for example, from 100 Å to 2,000 Å. Although a TEOS-based oxide is utilized for adhesion layers in some embodiments, other materials that provide for adhesion between later deposited layers and underlying layers or materials (e.g., ceramics, in particular, polycrystalline ceramics) can be utilized according to an embodiment of the present invention. For example, SiO₂ or other silicon oxides (SiₓO_{y}) grown using other oxide formation processes adhere well to ceramic materials and provide a suitable surface for subsequent deposition, for example, of conductive materials. In some embodiments, including the example structure shown in FIG. 1, the first adhesion layer 112 completely surrounds the core 110 to form a fully encapsulated core and can be formed using a low pressure chemical vapor deposition (LPCVD) process. The first adhesion layer 112 provides a surface on which subsequent layers adhere to form elements of the engineered substrate structure.

In addition to the use of LPCVD processes, furnace-based processes, and the like to form the encapsulating first adhesion layer, other semiconductor processes can be utilized according to embodiments of the present invention, including chemical vapor deposition (CVD) processes or similar deposition processes. As an example, a deposition process that coats a portion of the core can be utilized, the core can be flipped over, and the deposition process could be repeated to coat additional portions of the core. Thus, although LPCVD techniques are utilized in some embodiments to provide a fully encapsulated structure, other film formation techniques can be utilized depending on the particular application.

A conductive layer 114 is formed surrounding the first adhesion layer 112. In an embodiment, the conductive layer 114 is a shell of polysilicon (i.e., polycrystalline silicon) that is formed surrounding the first adhesion layer 112. In the illustrated embodiment, the first adhesion layer 112 is utilized since polysilicon can exhibit poor adhesion to ceramic materials. In embodiments in which the conductive layer is polysilicon, the thickness of the polysilicon layer can be on the order of 500-5,000 Å, for example, 2,500 Å. In some embodiments, the polysilicon layer can be formed as a shell to completely surround the first adhesion layer 112 (e.g., a TEOS-based oxide layer), thereby forming a fully encapsulated first adhesion layer, and can be formed using an LPCVD process. In other embodiments, the conductive material can be formed on a portion of the adhesion layer, for example, a lower half of the substrate structure. In some embodiments, conductive material can be formed as a fully encapsulating layer and subsequently removed on one side of the substrate structure.

In an embodiment, the conductive layer 114 can be a polysilicon layer doped to provide a highly conductive material, for example, doped with boron to provide a p-type polysilicon layer. In some embodiments, the doping with boron is at a level of 1×10¹⁹ cm⁻³ to 1×10²⁰ cm⁻³ to provide for high conductivity. Other dopants at different dopant concentrations (e.g., phosphorus, arsenic, bismuth, or the like at dopant concentrations ranging from 1×10¹⁶ cm⁻³ to 5×10¹⁸ cm⁻³) can be utilized to provide either n-type or p-type semiconductor materials suitable for use in the conductive layer. One of ordinary skill in the art would recognize many variations, modifications, and alternatives.

The presence of the conductive layer 114 is useful during electrostatic chucking of the engineered substrate to semiconductor processing tools, for example, tools with an electrostatic chuck (ESC). The conductive layer 114 enables rapid dechucking after processing in the semiconductor processing tools. Thus, embodiments of the present invention provide substrate structures that can be processed in manners utilized with conventional silicon wafers. One of ordinary skill in the art would recognize many variations, modifications, and alternatives.

A second adhesion layer 116 (e.g., a TEOS-based oxide layer on the order of 1,000 Å in thickness) is formed surrounding the conductive layer 114. In some embodiments, the second adhesion layer 116 completely surrounds the conductive layer 114 to form a fully encapsulated structure and can be formed using an LPCVD process, a CVD process, or any other suitable deposition process, including the deposition of a spin-on dielectric.

A diffusion barrier layer 118, for example, a silicon nitride layer, is formed surrounding the second adhesion layer 116. In an embodiment, the diffusion barrier layer 118 is a silicon nitride layer that is on the order of 2,000 Å to 5,000 Å in thickness. The diffusion barrier layer 118 completely surrounds the second adhesion layer 116 in some embodiments to form a fully encapsulated structure and can be formed using an LPCVD process. In addition to silicon nitride layers, amorphous materials including SiCN, SiON, AlN, SiC, and the like can be utilized as diffusion barrier layers. In some implementations, the diffusion barrier layer 118 comprises a number of sub-layers that are built up to form the diffusion barrier layer. Thus, the term diffusion barrier layer is not intended to denote a single layer or a single material, but to encompass one or more materials layered in a composite manner. One of ordinary skill in the art would recognize many variations, modifications, and alternatives.

In some embodiments, the diffusion barrier layer 118, e.g., a silicon nitride layer, prevents diffusion and/or outgassing of elements present in the core 110, for example, yttrium, yttria, oxygen, metallic impurities, other trace elements, and the like into the environment of the semiconductor processing chambers in which the engineered substrate could be present, for example, during a high temperature (e.g., 1,000° C.) epitaxial growth process. Importantly, utilizing the encapsulating layers described herein, ceramic materials, including polycrystalline AIN that are designed for non-clean room environments, can be utilized in semiconductor process flows and clean room environments. The expensive clean room environments are therefore protected.

In the example shown in FIG. 1, a bonding layer 120 (e.g., a silicon oxide layer) is deposited on a portion of the diffusion barrier layer 118, for example, the top surface of the diffusion barrier layer, and subsequently used during the bonding of a substantially single crystalline layer 122, e.g., a single crystal silicon layer. The bonding layer 120 can be approximately 1.5 μm in thickness in some embodiments.

The substantially single crystalline layer 122 is suitable for use as a growth layer during an epitaxial growth process for the formation of the device layers 190. In some embodiments, the device layers 190 include an epitaxial material layer. In one example, the epitaxial material layer includes a GaN layer 2 μm to 10 μm in thickness, which can be utilized as one of a plurality of layers utilized in optoelectronic devices, RF devices, power devices, and the like. In an embodiment, the substantially single crystalline layer 122 includes a substantially single crystalline silicon layer that is attached to the silicon oxide layer using a layer transfer process. In other embodiments, the substantially single crystalline layer 122 can include, for example, SiC, sapphire, GaN, AlN, SiGe, Ge, diamond, Ga₂O₃, AlGaN, InGaN, InN, and/or ZnO. In some embodiments, the substantially single crystalline layer 122 can have a thickness from 0 to 0.5 μm. The crystalline layers of the epitaxial material are an extension of the underlying semiconductor lattice associated with the substantially single crystalline layer 122. The unique CTE matching properties of the engineered substrate enable the growth of thicker epitaxial material than existing technologies.

As briefly discussed above, at an elevated temperature, binding agents such as yttrium-based compounds or other elements/compounds can migrate and consume layers of the engineered substrate. Although, as discussed in relation to FIGS. 2A-2C, diffusion of yttrium does not occur at substantial levels at temperatures up to 1,100° C., the inventors have determined that yttrium and/or yttria migration occurs at higher temperatures and can result in degradation of the quality of engineered layers present in the engineered substrate, including delamination of layers in some cases.

FIG. 2A is a secondary ion mass spectroscopy (SIMS) profile illustrating species concentration (as-deposited) as a function of depth for an engineered structure according to an embodiment of the present invention. The engineered structure did not include the diffusion barrier layer 118 shown in FIG. 1. Referring to FIG. 2A, several species present in the ceramic core (e.g., yttrium, calcium, and aluminum) drop to negligible concentrations in the bonding layer 120 and the substantially single crystalline layer 122 (collectively, the engineered layers 120/122). The concentrations of calcium, yttrium, and aluminum drop by three, four, and six orders of magnitude, respectively.

FIG. 2B is a SIMS profile illustrating species concentration (after anneal) as a function of depth for an engineered structure without a diffusion barrier layer according to an embodiment of the present invention. As discussed above, during semiconductor processing operations, the engineered substrate structures provided by embodiments of the present invention can be exposed to high temperatures (˜1,100° C.) for several hours, for example, during epitaxial growth of GaN-based layers.

For the profile illustrated in FIG. 2B, the engineered substrate structure was annealed at 1,100° C. for a period of four hours. As shown by FIG. 2B, calcium, yttrium, and aluminum, originally present in low concentrations in the as deposited sample, have diffused into the engineered layers, reaching concentrations similar to other elements.

FIG. 2C is a SIMS profile illustrating species concentration (after anneal) as a function of depth for an engineered structure with a diffusion barrier layer according to an embodiment of the present invention. The integration of the diffusion barrier layer 118 (e.g., a silicon nitride layer) into the engineered substrate structure prevents the diffusion of calcium, yttrium, and aluminum into the engineered layers during the annealing process that occurred when the diffusion barrier layer was not present. As illustrated in FIG. 2C, calcium, yttrium, and aluminum present in the ceramic core remain at low concentrations in the engineered layers post- anneal. Thus, the use of the diffusion barrier layer 118 (e.g., a silicon nitride layer) prevents these elements from diffusing through the diffusion barrier layer and thereby prevents their release into the environment surrounding the engineered substrate. Similarly, any other impurities contained within the bulk ceramic material would be contained by the diffusion barrier layer.

Typically, ceramic materials utilized to form the core 110 are fired at temperatures in the range of 1,800° C. It would be expected that this process would drive out a significant amount of impurities present in the ceramic materials. These impurities can include yttrium, which results from the use of yttria as sintering agent, calcium, and other elements and compounds. Subsequently, during epitaxial growth processes, which are conducted at much lower temperatures in the range of 800° C. to 1,100° C., it would be expected that the subsequent diffusion of these impurities would be insignificant. However, contrary to conventional expectations, the inventors have determined that even during epitaxial growth processes at temperatures much less than the firing temperature of the ceramic materials, significant diffusion of elements through the layers of the engineered substrate can occur. Thus, as shown in FIG. 2C in contrast to FIG. 2B, the diffusion barrier layer 118 (e.g., a silicon nitride layer) can prevent out-diffusion of the background elements from the polycrystalline ceramic material (e.g., AlN) into the engineered layers 120/122 and the device layers 190. The diffusion barrier layer 118 encapsulating the underlying layers and material provides the desired diffusion barrier layer functionality.

As illustrated in FIG. 2B, elements originally present in the core 110, including yttrium, diffuse into and through the first adhesion layer 112, the conductive layer 114, and the second adhesion layer 116. However, the presence of the diffusion barrier layer 118 prevents these elements from diffusing through the diffusion barrier layer 118 and thereby prevents their release into the environment surrounding the engineered substrate at annealing temperatures up to 1,100° C., as illustrated in FIG. 2C.

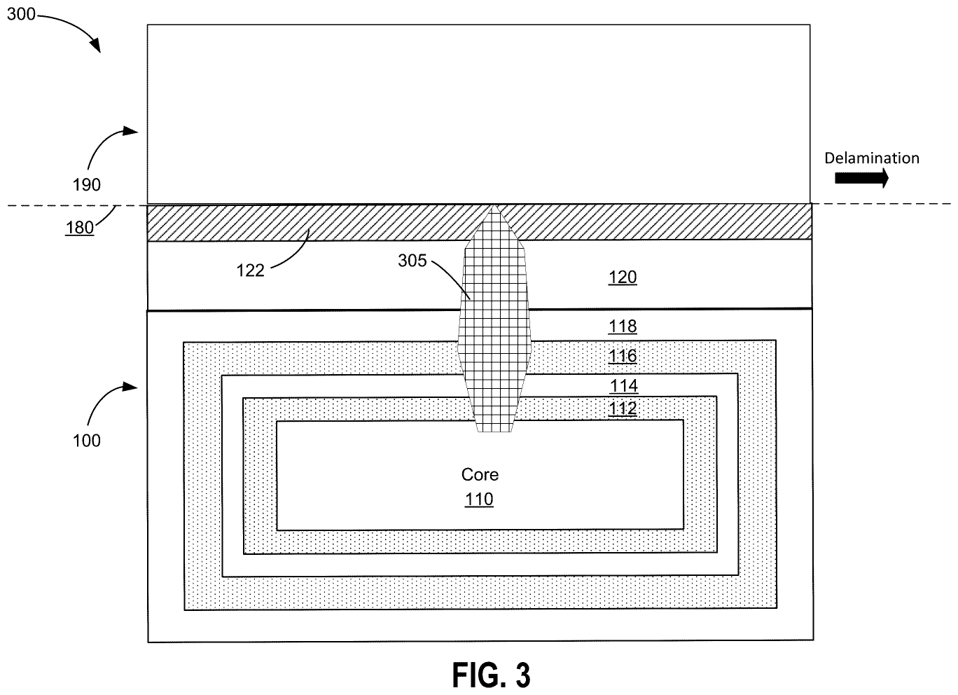

However, as mentioned above, the inventors have observed that the diffusion barrier layer 118 illustrated in FIGS. 1 and 3, for example, a silicon nitride layer, which prevents diffusion and/or outgassing of elements present in the core 110 of the engineered substrate at epitaxial growth temperatures on the order of 1,100° C., does not prevent the migration of yttrium-based compounds, including yttria, at elevated temperatures greater than 1,100° C.

FIG. 3 is a simplified schematic diagram illustrating a semiconductor device with yttrium-based compound migration according to an embodiment of the present invention. As illustrated in FIG. 3, an engineered substrate 300 in which an yttrium-based compound structure 305 is formed as the yttrium-based compounds (e.g., yttria) in the core 110 consume a portion of one or more of the core 110, the first adhesion layer 112, the conductive layer 114, the second adhesion layer 116, the diffusion barrier layer 118, the bonding layer 120, and/or the substantially single crystalline layer 122. The yttria percent composition (by weight) in the core 110 is typically between 1% and 5%, for example, in some cases, between 3% and 5%. At these concentrations, binding agent grains will be exposed at the surface of the polycrystalline ceramic core (rather than being covered by the material of the polycrystalline ceramic core) and, therefore, in physical contact with adjacent layers, including layers containing silicon and/or oxygen. Thus, as discussed above, the binding agent can react with and consume one or more films/layers in the engineered substrate 300, which may cause localized delamination where the yttrium-based compound structure 305 deforms the interface 180 between the engineered substrate 300 and the device layers 190.

As discussed above, the polycrystalline ceramic core can include not only polycrystalline AlN or other suitable materials, but also yttrium-based materials, including yttria, as a binding agent. For many GaN-based semiconductor process steps, including epitaxial growth, the processing temperatures are under 1100° C. and the diffusion barrier layer 118 illustrated in FIG. 1 is sufficient to prevent diffusion of yttrium-based compounds, including yttria, through the diffusion barrier layer as shown in FIG. 2C. However, the inventors have determined that at high temperatures associated with some semiconductor processes, for instance, implant activation, (e.g., temperatures greater than 1100° C., for example, on the order of 1200° C. or 1300° C.), the yttrium-based compounds present in the polycrystalline ceramic core can migrate and subsequently react, for example, with silicon-containing materials, including silicon oxide, silicon nitride, and polycrystalline silicon and/or oxygen-containing materials.

Without limiting embodiments of the present invention, the inventors believe that yttrium and silicon, either as single crystal silicon or polycrystalline silicon, form a eutectic mixture that melts at a temperature lower than the melting points of either yttrium or silicon. As a result, at elevated temperatures, the yttrium and/or yttria migrates through silicon-containing layers as illustrated in FIG. 3. At these elevated temperatures greater than 1100° C., for example, on the order of 1200° C. or 1300° C., the diffusion barrier layer 118 is not effective in preventing the migration of the eutectic mixture, although it can be sufficient to prevent the atomic or molecular diffusion of elements such as yttrium, as shown in FIG. 2C.

Referring to FIG. 3, the yttrium-based compound structure 305 may migrate or penetrate through a portion of one or more of the core 110, the first adhesion layer 112, the conductive layer 114, the second adhesion layer 116, the diffusion barrier layer 118, the bonding layer 120, and/or the substantially single crystalline layer 122. In some examples, the yttrium-based compound structure 305 may even reach the interface 180 between the engineered substrate 300 and the device layers 190. As a result, the mechanical bonding strength between the engineered substrate 100 and the device layers 190 is weakened. Therefore, delamination of the device layers 190 may occur, as illustrated by the arrow shown in FIG. 3.

In order to address problems resulting from the migration of yttrium-based compounds from the polycrystalline ceramic core and consumption of engineered films coupled to the polycrystalline ceramic core as illustrated in FIG. 3, embodiments of the present invention provide a multi-core engineered substrate that includes a polycrystalline ceramic core with yttrium-based compounds and one or more layers free of yttrium-based compounds, for example, yttria. These layer(s) that are free of yttrium-based compounds may be referred to as yttria-free layer(s). As described more fully herein, the one or more layers free of yttrium-based compounds can serve to prevent yttrium-based compounds present in the polycrystalline ceramic core from migrating from the polycrystalline ceramic core to outer portions of the engineered substrate, particularly, layers of the engineered substrate adjacent the diffusion barrier layer 118, the bonding layer 120, and the substantially single crystalline layer 122.

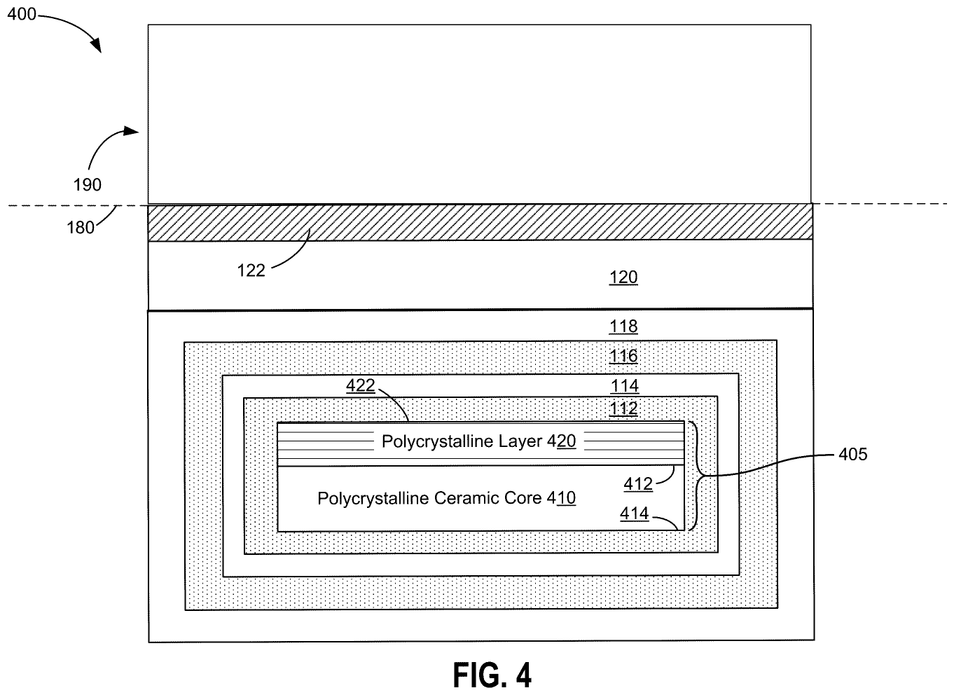

FIG. 4 is a simplified schematic diagram illustrating a multi-core engineered substrate structure according to an embodiment of the present invention. The multi-core engineered substrate 400 illustrated in FIG. 4 shares common elements with the engineered substrate illustrated in FIG. 1 and the discussion provided in relation to the engineered substrate illustrated in FIG. 1 is applicable to the multi-core engineered substrate illustrated in FIG. 4 as appropriate.

Referring to FIG. 4, ceramic core 405 includes polycrystalline ceramic core 410 and polycrystalline layer 420. Accordingly, ceramic core 405 can be referred to as a multi-layer ceramic core.

Polycrystalline ceramic core 410 can be referred to as a primary core and polycrystalline layer 420 can be referred to as a secondary core. Polycrystalline ceramic core 410 can be similar in materials and construction to core 110, including binders such as yttrium-based compounds. In some embodiments, polycrystalline grains, e.g., polycrystalline AlN grains, and a binding agent, e.g., a yttrium-based compound, are used to form polycrystalline ceramic core 410. Polycrystalline ceramic core 410 has a device surface 412 and a support surface 414 opposite device surface 412. As an example, the polycrystalline grains can include polycrystalline AlN grains or silicon carbide grains. The binding agent can include yttrium aluminum garnet or other suitable yttrium-based compounds. Generally, the polycrystalline grains in polycrystalline ceramic core 410 have a grain size on the order of a few microns to a few tens of microns.

Polycrystalline layer 420 is coupled to device surface 412 and free of binding agents, including yttrium-based compounds and, therefore, is free of yttrium and yttria. In the present specification, the term “free of yttrium” includes ceramic materials, particularly, polycrystalline layer 420, that have an yttrium concentration less than 1% by weight, less than 0.5% by weight, or less than 0.1% by weight. In some embodiments, polycrystalline grains, e.g., polycrystalline AlN grains, are utilized with no binding agent to form polycrystalline layer 420. Thus, polycrystalline layer 420 can consist of AlN grains, SiC grains, GaN grains, AlGaN grains, ZnO grains, Ga₂O₃ grains, combinations of these grains, or the like. The polycrystalline grains making up polycrystalline layer 420 can be characterized by a grain size on the order of the grain size of the grains used to form polycrystalline ceramic core 410. In other embodiments, the polycrystalline grains making up polycrystalline layer 420 can be characterized by a grain size less than the grain size of the grains used to form polycrystalline ceramic core 410. Merely by way of example, grains used to form polycrystalline ceramic core 410 can be on the order of 10 μm, whereas grains used to form polycrystalline layer 420 can be on the order of 1 μm-5 μm.

During sintering of ceramic core 405, an yttrium-free layer is formed as polycrystalline layer 420 is joined to device surface 412. As described herein, although yttrium is present in polycrystalline ceramic core 410, the presence of polycrystalline layer 420 prevents migration of yttrium and/or yttrium-based compounds that would otherwise react with engineered films coupled to polycrystalline layer 420. After formation of ceramic core 405, additional engineered films and layers can be formed as illustrated in FIG. 4, thereby providing an engineered substrate suitable for use in epitaxial growth and other semiconductor processes.

In some embodiments, the bulk of ceramic core 405 is formed by polycrystalline ceramic core 410, with a thickness ranging from 100 μm to 1,500 μm. In these embodiments, the thickness of polycrystalline layer 420 is on the order of 10 μm to 100 μm. In other embodiments, differing thicknesses can be utilized, but the inventors have determined that a relatively thin layer of yttrium-free ceramic material in comparison to the thickness of the primary core is sufficient to prevent yttrium and/or yttrium-based compound migration through polycrystalline layer 420, even at elevated temperatures, e.g., temperatures between 1,100° C. and 1,300° C.

The composition of the grains used to form polycrystalline ceramic core 410 and polycrystalline layer 420 can be the same or different. As an example, polycrystalline ceramic core 410 can include AlN grains and a binding agent and polycrystalline layer 420 can also include AlN grains. As another example, polycrystalline ceramic core 410 can include AlN grains and a binding agent and polycrystalline layer 420 can include SiC grains. In some embodiments, multiple grain types are utilized, for example, AlN and GaN grains joined using a binding agent for polycrystalline ceramic core 410, or SiC grains joined using a binding agent, or combinations thereof, and AlN or SiC grains for polycrystalline layer 420. One of ordinary skill in the art would recognize many variations, modifications, and alternatives.

In some embodiments, the thermal conductivity of polycrystalline ceramic core 410 and polycrystalline layer 420 are matched, i.e., equal. Moreover, the CTE of polycrystalline ceramic core 410 and polycrystalline layer 420 can be matched, i.e., equal, and also equal to the CTE of epitaxial layers grown on the engineered substrate, for example, device layers 190.

Embodiments of the present invention can be fabricated in several ways, depending on the particular fabrication process. As an example, a sintering process can be used to join polycrystalline layer 420 to polycrystalline ceramic core 410. This sintering process is particularly useful in cases for which polycrystalline ceramic core 410 makes up the bulk of ceramic core 405, i.e., the thickness of polycrystalline layer 420 is on the order of tens of microns. In another embodiment, polycrystalline layer 420 is deposited on polycrystalline ceramic core 410.

As an example, polycrystalline or amorphous materials can be deposited on polycrystalline ceramic core 410 using a semiconductor deposition chamber/process. Deposition processes that can be utilized by embodiments of the present invention include CVD, plasma-enhanced CVD (PECVD), Hydride vapor-phase epitaxy (HVPE), physical vapor transport (PVT), sometimes called physical vapor deposition (PVD), or the like. These deposition processes can provide not only high purity, but high density films. The deposited materials can be a variety of materials including AlN, SiC, GaN, AlGaN, ZnO, Ga₂O₃, Al₂O₃, AlON, combinations, thereof, or the like. For instance, polycrystalline AlN can be deposited, e.g., a layer a few tens of microns thick, on polycrystalline ceramic core 410.

The use of a deposition process to form polycrystalline layer 420 can provide a continuous film with a higher density than that achieved using sintering processes. Moreover, after deposition, one or more polishing/etching processes can be utilized to form polycrystalline layer 420 in such a manner that it is substantially free of voids, particularly in comparison to polycrystalline layers that are sintered. In some embodiments, polycrystalline layer 420 can be deposited with a first thickness, e.g., 50 μm -100 μm, then polished or etched to form a layer with reduced thickness, e.g., 1 μm-20 μm. Polishing and/or etching of polycrystalline layer 420 can reduce the surface roughness of surface 422, thereby providing a more uniform surface for deposition of first adhesion layer 112. Thus, embodiments of the present invention provide polycrystalline layer 420, not only as a migration barrier to yttrium and/or yttrium-based compounds, but as a smooth, void-free layer for subsequent deposition processes. Moreover, in some embodiments, multiple deposition and polishing processes can be utilized to form polycrystalline layer 420 by depositing layer of an yttrium-free material, polishing the layer of yttrium-free material to remove a portion of the layer, depositing a second layer of the same or another yttrium-free material, polishing the second layer to remove a portion of the second layer, and repeating one or both of the deposition/polishing steps to form the polycrystalline layer 420. One of ordinary skill in the art would recognize many variations, modifications, and alternatives.

In some embodiments, the multi-core engineered substrate 400 further includes a first adhesion layer coupled to the polycrystalline layer, a conductive layer coupled to the first adhesion layer, a second adhesion layer coupled to the conductive layer, and a diffusion barrier layer coupled to the second adhesion layer. The engineered substrate in these embodiments additionally includes a bonding layer coupled to the diffusion barrier layer, a substantially single crystal coupled to the bonding layer, and an epitaxial III-V layer coupled to the substantially single crystal layer. The first adhesion layer can encapsulate the polycrystalline layer, the conductive layer can encapsulate the first adhesion layer, the second adhesion layer can encapsulate the conductive layer, and the diffusion barrier layer can encapsulate the second adhesion layer. The conductive layer can be a polysilicon layer. The bonding layer can be a silicon oxide layer. The substantially single crystal layer can be a single crystal silicon layer. The epitaxial III-V layer can be an epitaxial GaN layer.

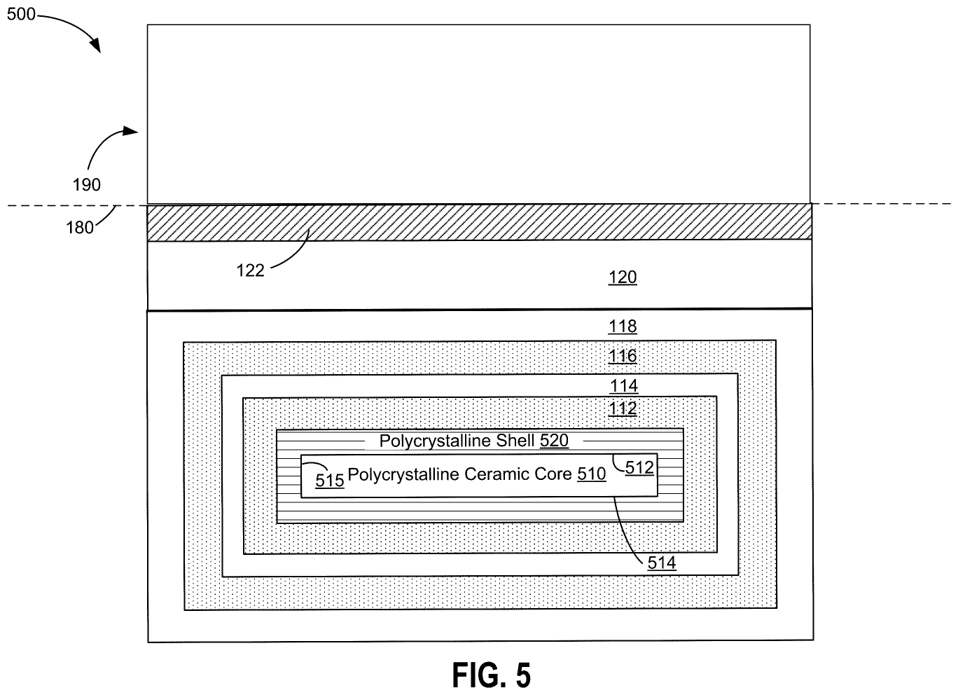

FIG. 5 is a simplified schematic diagram illustrating a multi-core engineered substrate structure according to another embodiment of the present invention. The multi-core engineered substrate 500 illustrated in FIG. 5 shares common elements with the multi-core engineered substrate 400 illustrated in FIG. 4 and the discussion provided in relation to the multi-core engineered substrate 400 illustrated in FIG. 4 is applicable to the multi-core engineered substrate 500 illustrated in FIG. 5 as appropriate.

Polycrystalline ceramic core 510 can be similar in materials and construction to polycrystalline ceramic core 410, including binders such as yttrium-based compounds. In some embodiments, polycrystalline grains, e.g., polycrystalline AlN grains, and a binding agent, e.g., a yttrium-based compound, are used to form polycrystalline ceramic core 510. As an example, the polycrystalline grains can include polycrystalline AlN grains or silicon carbide grains. The binding agent can include yttrium aluminum garnet or other suitable yttrium-based compounds. Generally, the polycrystalline grains in polycrystalline ceramic core 510 have a grain size on the order of a few microns to a few tens of microns.

Polycrystalline shell 520 encapsulates polycrystalline ceramic core 510 and is free of binding agents, including yttrium-based compounds and, therefore, is free of yttrium and yttria. In some embodiments, polycrystalline grains, e.g., polycrystalline AlN grains, are utilized with no binding agent to form polycrystalline shell 520. Thus, polycrystalline shell 520 can consist of AlN grains, SiC grains, GaN grains, AlGaN grains, ZnO grains, Ga₂O₃ grains, combinations of these grains, or the like. The polycrystalline grains making up polycrystalline shell 520 can be characterized by a grain size on the order of the grain size of the grains used to form polycrystalline ceramic core 510. In other embodiments, the polycrystalline grains making up polycrystalline shell 520 can be characterized by a grain size less than the grain size of the grains used to form polycrystalline ceramic core 510. Merely by way of example, grains used to form polycrystalline ceramic core 510 can be on the order of 10 μm, whereas grains used to form polycrystalline shell 520 can be on the order of 1 μm-5 μm.

The polycrystalline shell 520 can be fabricated by sintering, deposition, deposition/polishing or other suitable methods. After formation of polycrystalline shell 520, additional engineered films and layers can be formed as illustrated in FIG. 5, thereby providing an engineered substrate suitable for use in epitaxial growth and other semiconductor processes.

In some embodiments, the polycrystalline ceramic core 510 has a thickness ranging from 100 μm to 1,500 μm and the thickness of polycrystalline shell 520 is on the order of 10 μm to 100 μm. In other embodiments, differing thicknesses can be utilized, but the inventors have determined that a relatively thin layer of yttrium-free ceramic material in comparison to the thickness of the primary core is sufficient to prevent yttrium and/or yttrium-based compound migration through polycrystalline shell 520, even at elevated temperatures, e.g., temperatures between 1,100° C. and 1,300° C.

The composition of the grains used to form polycrystalline ceramic core 510 and polycrystalline shell 520 can be the same or different. As an example, polycrystalline ceramic core 510 can include AlN grains and a binding agent and polycrystalline shell 520 can also include AlN grains. As another example, polycrystalline ceramic core 510 can include AlN grains and a binding agent and polycrystalline shell 520 can include SiC grains. In some embodiments, multiple grain types are utilized, for example, AlN and GaN grains joined using a binding agent for polycrystalline ceramic core 510, or SiC grains joined using a binding agent, or combinations thereof, and AlN or SiC grains for polycrystalline shell 520. One of ordinary skill in the art would recognize many variations, modifications, and alternatives.

In some embodiments, the thermal conductivity of polycrystalline ceramic core 510 and polycrystalline shell 520 are matched, i.e., equal. Moreover, the CTE of polycrystalline ceramic core 510 and polycrystalline shell 520 can be matched, i.e., equal, and also equal to the CTE of epitaxial layers grown on the engineered substrate, for example, device layers 190.

Embodiments of the present invention can be fabricated in several ways, depending on the particular fabrication process. As an example, a sintering process can be used to form polycrystalline shell. In another embodiment, polycrystalline shell 520 is deposited on polycrystalline ceramic core 510 using techniques discussed in relation to deposition and/or deposition/polishing of polycrystalline layer 420.

As an example, polycrystalline or amorphous materials can be deposited on polycrystalline ceramic core 510 using a semiconductor deposition chamber/process. The deposited materials can be a variety of materials including AlN, SiC, GaN, AlGaN, ZnO, Ga₂O₃, Al₂O₃, AlON, combinations, thereof, or the like. For instance, polycrystalline AlN can be deposited, e.g., a layer a few tens of microns thick, on polycrystalline ceramic core 510.

In some embodiments, the multi-core engineered substrate 500 further includes a first adhesion layer coupled to the polycrystalline layer, a conductive layer coupled to the first adhesion layer, a second adhesion layer coupled to the conductive layer, and a diffusion barrier layer coupled to the second adhesion layer. The engineered substrate in these embodiments additionally includes a bonding layer coupled to the diffusion barrier layer, a substantially single crystal coupled to the bonding layer, and an epitaxial III-V layer coupled to the substantially single crystal layer. The first adhesion layer can encapsulate the polycrystalline layer, the conductive layer can encapsulate the first adhesion layer, the second adhesion layer can encapsulate the conductive layer, and the diffusion barrier layer can encapsulate the second adhesion layer. The conductive layer can be a polysilicon layer. The bonding layer can be a silicon oxide layer. The substantially single crystal layer can be a single crystal silicon layer. The epitaxial III-V layer can be an epitaxial GaN layer.

Referring to FIG. 5, polycrystalline ceramic core 510 is encapsulated, i.e., surrounded on all sides, by polycrystalline shell 520. Thus, as illustrated in FIG. 5, the device surface 512, the support surface 514 opposite the device surface, and the peripheral surfaces 515 extending between the device surface and the support surface are encapsulated by polycrystalline shell 520. Thus, in comparison to the embodiment illustrated in FIG. 4, not only is the polycrystalline shell free of a binding agent coupled to device surface 512, but also to support surface 514, as well as the side surfaces (i.e., the peripheral surfaces 515) of polycrystalline ceramic core 510. As a result, the polycrystalline ceramic core is encapsulated, thereby preventing yttrium and and/or yttrium-based compounds a migration from the polycrystalline ceramic core to the adjacent semiconductor layers.

As discussed above, the process utilized to form polycrystalline layer 420 illustrated in FIG. 4 can be utilized to form polycrystalline shell 520 illustrated in FIG. 5.

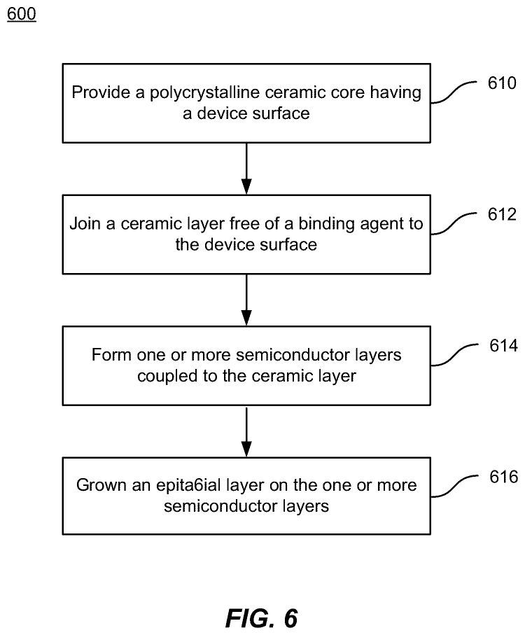

FIG. 6 is a simplified flowchart illustrating a method of fabricating a multi-core engineered substrate structure according to an embodiment of the present invention. The method 600 includes providing a polycrystalline ceramic core having a device surface (610) and joining a ceramic layer free of a binding agent to the device surface (612). The ceramic layer can be a polycrystalline layer or an amorphous layer. In some embodiments, the binding agent includes yttria and, as a result, the ceramic layer is free of yttrium. In various embodiments, the ceramic layer consists of AlN, SiC, GaN, AlGaN, ZnO, Ga₂O₃, Al₂O₃, AlON, combinations, thereof, or the like. The polycrystalline ceramic core and the ceramic layer can be sintered together, for example, at a temperature of ˜1,800° C.

The method also includes forming one or more semiconductor layers coupled to the ceramic layer (614) and growing an epitaxial layer on one of the one or more semiconductor layers (616). The polycrystalline ceramic core can have a thickness ranging from 100 μm to 1,500 μm and the ceramic layer can have a thickness ranging from 10 μm to 100 μm. In some embodiments, the polycrystalline ceramic core and the ceramic layer are sintered and then the ceramic layer is polished to improve the surface morphology of the ceramic layer. In these embodiments, after polishing, the ceramic layer can have a thickness ranging from 1 μm to 10 μm. Moreover, the ceramic layer can be a continuous film in contact with the polycrystalline ceramic core.

It should be appreciated that the specific steps illustrated in FIG. 6 provide a particular method of fabricating a multi-core engineered substrate structure according to an embodiment of the present invention. Other sequences of steps may also be performed according to alternative embodiments. For example, alternative embodiments of the present invention may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. One of ordinary skill in the art would recognize many variations, modifications, and alternatives.

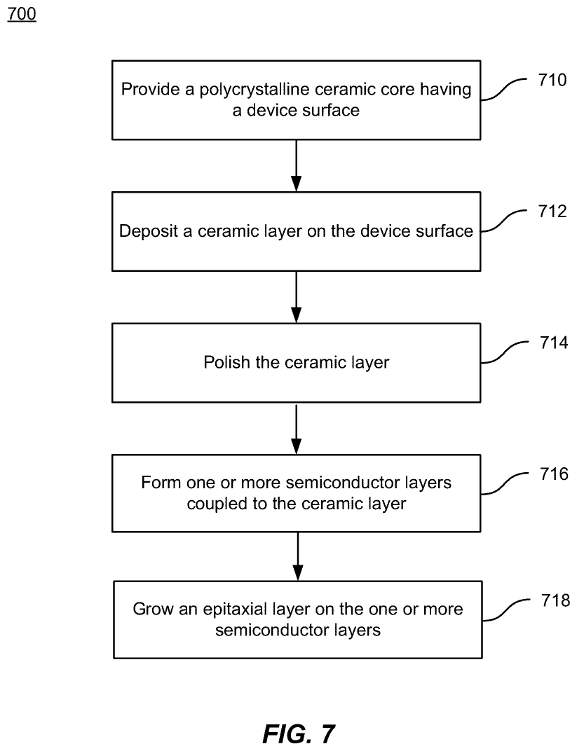

FIG. 7 is a simplified flowchart illustrating a method of fabricating a multi-core engineered substrate structure by deposition and polishing of a polycrystalline layer according to an embodiment of the present invention. The method 700 includes providing a polycrystalline ceramic core having a device surface (710) and depositing a ceramic layer on the device surface (712). The method also includes polishing the ceramic layer (714), forming one or more semiconductor layers coupled to the ceramic layer (716), and growing an epitaxial layer on one of the one or more semiconductor layers (718). In an embodiment, after polishing the ceramic layer, the ceramic layer has a thickness ranging from 1 μm to 10 μm.

After polishing the ceramic layer, the ceramic layer can have a thickness ranging from 1 μm to 10 μm. The ceramic layer can be a polycrystalline layer or an amorphous layer. The ceramic layer is free of yttrium in some embodiments. The ceramic layer can be a continuous film. The polycrystalline ceramic core can have a thickness ranging from 100 μm to 1,500 μm and the ceramic layer can have a thickness ranging from 10 μm to 100 μm. The ceramic layer can consist of aluminum nitride, aluminum oxide nitride, aluminum oxide, or silicon carbide. The method can also include polishing the ceramic layer. After polishing, the ceramic layer can have a thickness ranging from 1 μm to 10 μm.

As discussed herein, the ceramic layers prevents migration of yttrium present in yttrium-based compounds from the polycrystalline ceramic core into the adjacent layers. Moreover, since the number of voids can be reduced by the polishing process, the number of defects present in the as-grown epitaxial material can also be reduced. Although polishing is discussed in relation to FIG. 7, it will be evident to one of skill in the art that etching or combined polishing/etching processes can be utilized to process the ceramic layer after deposition or between deposition processes. One of ordinary skill in the art would recognize many variations, modifications, and alternatives.

It should be appreciated that the specific steps illustrated in FIG. 7 provide a particular method of fabricating a multi-core engineered substrate structure by deposition and polishing of a polycrystalline layer according to an embodiment of the present invention. Other sequences of steps may also be performed according to alternative embodiments. For example, alternative embodiments of the present invention may perform the steps outlined above in a different order. Moreover, the individual steps illustrated in FIG. 7 may include multiple sub-steps that may be performed in various sequences as appropriate to the individual step. Furthermore, additional steps may be added or removed depending on the particular applications. One of ordinary skill in the art would recognize many variations, modifications, and alternatives.

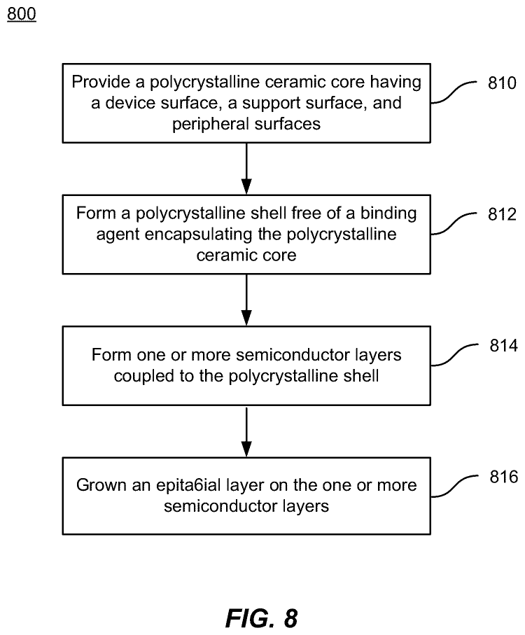

FIG. 8 is a simplified flowchart illustrating a method of fabricating a multi-core engineered substrate structure with a polycrystalline shell according to an embodiment of the present invention. The method 800 includes providing a polycrystalline ceramic core having a device surface, a support surface opposite the device surface, and peripheral surfaces extending between the device surface and the support surface (810) and forming a polycrystalline shell encapsulating the polycrystalline ceramic core (812). The polycrystalline shell is free of a binding agent. The method also includes forming one or more semiconductor layers coupled to the polycrystalline shell (814) and growing an epitaxial layer on one of the one or more semiconductor layers (816). The polycrystalline shell can be free of yttrium and can be formed as a continuous film. The polycrystalline ceramic core can have a thickness ranging from 100 μm to 1,500 μm and the polycrystalline shell can have a thickness ranging from 10 μm to 100 μm. The polycrystalline shell can consist of aluminum nitride, aluminum oxide nitride, aluminum oxide, or silicon carbide.

It should be appreciated that the specific steps illustrated in FIG. 8 provide a particular method of fabricating a multi-core engineered substrate structure with a polycrystalline shell according to an embodiment of the present invention. Other sequences of steps may also be performed according to alternative embodiments. For example, alternative embodiments of the present invention may perform the steps outlined above in a different order. Moreover, the individual steps illustrated in FIG. 8 may include multiple sub-steps that may be performed in various sequences as appropriate to the individual step. Furthermore, additional steps may be added or removed depending on the particular applications. One of ordinary skill in the art would recognize many variations, modifications, and alternatives.

It is also understood that the examples and embodiments described herein are for illustrative purposes only and that various modifications or changes in light thereof will be suggested to persons skilled in the art and are to be included within the spirit and purview of this application and scope of the appended claims.

1. An engineered substrate comprising:
a polycrystalline ceramic core having a device surface and a support surface opposite the device surface; and
a polycrystalline layer free of a binding agent coupled to the device surface.

2. The engineered substrate of claim 1 wherein the polycrystalline ceramic core comprises polycrystalline grains and the binding agent.

3. The engineered substrate of claim 2 wherein the polycrystalline grains comprise aluminum nitride.

4. The engineered substrate of claim 2 wherein the binding agent comprises yttrium aluminum garnet.

5. The engineered substrate of claim 2 wherein the polycrystalline grains are characterized by a grain size ranging from 1 μm to 20 μm.

6. The engineered substrate of claim 1 wherein the polycrystalline ceramic core has a thickness ranging from 100 μm to 1,500 μm and the polycrystalline layer has a thickness ranging from 10 μm to 100 μm.

7. The engineered substrate of claim 1 wherein the polycrystalline layer consists of aluminum nitride.

8. The engineered substrate of claim 1 wherein the polycrystalline layer consists of silicon carbide.

9. The engineered substrate of claim 1 wherein the polycrystalline layer is free of yttrium.

10. The engineered substrate of claim 1 wherein the polycrystalline layer has an yttrium concentration less than 1% by weight.

11. The engineered substrate of claim 1 wherein a thermal conductivity of the polycrystalline ceramic core and the polycrystalline layer are equal.

12. The engineered substrate of claim 1 wherein a coefficient of thermal expansion of the polycrystalline ceramic core and the polycrystalline layer are equal.

13. The engineered substrate of claim 12 further comprising an epitaxial device layer coupled to the polycrystalline layer, wherein the coefficient of thermal expansion of the polycrystalline ceramic core and the epitaxial device layer are equal.

14. The engineered substrate of claim 1 wherein the polycrystalline layer is substantially free of voids.

15. The engineered substrate of claim 1 wherein the polycrystalline layer comprises a continuous film.

16. The engineered substrate of claim 1 further comprising:
a first adhesion layer coupled to the polycrystalline layer;
a conductive layer coupled to the first adhesion layer;
a second adhesion layer coupled to the conductive layer; and
a diffusion barrier layer coupled to the second adhesion layer;
a bonding layer coupled to the diffusion barrier layer;
a substantially single crystal layer coupled to the bonding layer; and
an epitaxial III-V layer coupled to the substantially single crystal layer.

17. The engineered substrate of claim 16 wherein:
the first adhesion layer encapsulates the polycrystalline layer;
the conductive layer encapsulates the first adhesion layer;
the second adhesion layer encapsulates the conductive layer; and
the diffusion barrier layer encapsulates the second adhesion layer.

18. The engineered substrate of claim 16 wherein the conductive layer comprises a polysilicon layer, the bonding layer comprises a silicon oxide layer, the substantially single crystal layer comprises a single crystal silicon layer, and the epitaxial III-V layer comprises an epitaxial gallium nitride layer.

19.-21. (Canceled).

22. The engineered substrate of claim 1 further comprising a second polycrystalline layer free of the binding agent coupled to the support surface.

23. The engineered substrate of claim 22 wherein the polycrystalline layer and the second polycrystalline layer encapsulate the polycrystalline ceramic core.

24.-66. (Canceled).
